(19) United States
(12) Patent Application Publication
(10) Pub. No.: US 2025/0087636 A1
(43) Pub. Date: Mar. 13, 2025

(54) SEMICONDUCTOR PACKAGE

(71) Applicant: Samsung Electronics Co., Ltd., Suwon-si (KR)

(72) Inventor: Inhee YOO, Suwon-si (KR)

(73) Assignee: Samsung Electronics Co., Ltd., Suwon-si (KR)

(21) Appl. No.: 18/679,639

(22) Filed: May 31, 2024

(30) Foreign Application Priority Data
Sep. 11, 2023 (KR) 10-2023-0120343

(51) Int. Cl. H01L 25/065; H01L 23/00; H01L 23/31

(52) U.S. Cl. CPC H01L 25/0652; H01L 23/3128; H01L 24/04; H01L 24/32; H01L 24/33; H01L 24/48; H01L 24/73; H01L 2224/04042; H01L 2224/32145; H01L 2224/32225; H01L 2224/33181; H01L 2224/48137; H01L 2224/48227; H01L 2224/73215; H01L 2224/73265; H01L 2225/06506; H01L 2225/0651

(57) ABSTRACT

A semiconductor package includes a package substrate including an insulating layer, an interconnection layer in the insulating layer, and interconnection pads on the insulating layer and electrically connected to the interconnection layer, first and second semiconductor chips on the package substrate and spaced apart from each other, first connection wires each extending from a first side of the first semiconductor chip to a second side of the second semiconductor chip and spaced apart from each other, an adhesive layer on the first and second semiconductor chips and covering at least a portion of each of the first connection wires, an upper semiconductor chip on the adhesive layer, second connection wires connecting the first and second semiconductor chips and the upper semiconductor chip to the interconnection layer of the package substrate, and an encapsulant on the package substrate and filling a space between the first and second semiconductor chips.

### CROSS-REFERENCE TO RELATED APPLICATION(S)

This application claims benefit of priority to Korean Patent Application No. 10-2023-0120343 filed on Sep. 11, 2023, in the Korean Intellectual Property Office, the disclosure of which is incorporated herein by reference in its entirety.

### BACKGROUND

The present inventive concepts relate to a semiconductor package.

Recently, there has been demand for increased performance and increased capacity in semiconductor packages installed in electronic devices. A three-dimensional structure in which at least one upper semiconductor chip is disposed on a plurality of lower semiconductor chips spaced apart from each other has been developed.

### SUMMARY

An aspect of the present inventive concepts is to provide a semiconductor package having improved reliability.

According to an aspect of the present inventive concepts, a semiconductor package includes: a package substrate including an insulating layer, an interconnection layer in the insulating layer, and interconnection pads on the insulating layer and electrically connected to the interconnection layer; first and second lower semiconductor chips over the package substrate, the first and second lower semiconductor chips spaced apart from each other in a first direction; first connection wires extending from a first side of the first lower semiconductor chip towards a second side of the second lower semiconductor chip, the first connection wires spaced apart from each other in a second direction, the second direction intersecting the first direction; an adhesive layer over the first and second lower semiconductor chips, the adhesive layer covering at least a portion of each of the first connection wires; an upper semiconductor chip over the adhesive layer; second connection wires electrically connecting the first and second lower semiconductor chips and the upper semiconductor chip to the interconnection layer of the package substrate; and an encapsulant on the package substrate, the encapsulant filling a space between the first and second semiconductor chips.

According to an aspect of the present inventive concepts, a semiconductor package includes: a package substrate; a plurality of lower semiconductor chips spaced apart from each other on the package substrate; first connection wires overlapping a space between two adjacent lower semiconductor chips, among the plurality of lower semiconductor chips, in a vertical direction, the first connection wires connecting the two adjacent lower semiconductor chips; second connection wires electrically connecting at least one of the plurality of lower semiconductor chips to the package substrate; an adhesive layer over the plurality of lower semiconductor chips, the adhesion layer covering at least a portion of each of the first connection wires; an upper semiconductor chip disposed on the adhesive layer; and an encapsulant covering at least a portion of each of the upper semiconductor chip and the plurality of lower semiconductor chips.

According to an aspect of the present inventive concepts, a semiconductor package includes: a package substrate; a first chip structure including a plurality of lower semiconductor chips on the package substrate and spaced apart from each other, lower connection wires connecting the plurality of lower semiconductor chips, a lower adhesive layer on the plurality of lower semiconductor chips and covering the lower connection wires, and an upper semiconductor chip on the lower adhesive layer; a second chip structure spaced apart from the first chip structure; upper connection wires connecting the first and second chip structures to each other; an upper adhesive layer on each of the first and second chip structures and covering the upper connection wires; and an uppermost semiconductor chip on the upper adhesive layer.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a cross-sectional view illustrating a semiconductor package according to at least one example embodiment of the present inventive concepts, and FIG. 1B is a plan view illustrating some components of the semiconductor package according to at least one example embodiment of the present inventive concepts;

FIG. 2A is a cross-sectional view illustrating a semiconductor package according to at least one example embodiment of the present inventive concepts, and FIG. 2B is a top view illustrating the semiconductor package according to at least one example embodiment of the present inventive concepts;

FIG. 3A is a cross-sectional view illustrating a semiconductor package according to at least one example embodiment of the present inventive concepts, FIG. 3B is a plan view illustrating some components of the semiconductor package according to at least one example embodiment of the present inventive concepts, and FIG. 3C is a top view illustrating the semiconductor package according to at least one example embodiment of the present inventive concepts;

FIG. 4A is a cross-sectional view illustrating a semiconductor package according to at least one example embodiment of the present inventive concepts, and FIG. 4B is a plan view illustrating some components of the semiconductor package according to at least one example embodiment of the present inventive concepts;

FIG. 5A is a cross-sectional view illustrating a semiconductor package according to at least one example embodiment of the present inventive concepts, and FIG. 5B is a plan view illustrating some components of the semiconductor package according to at least one example embodiment of the present inventive concepts; and

FIGS. 6A to 6D are cross-sectional views illustrating a main process of a method of manufacturing a semiconductor package according to at least one example embodiment of the present inventive concepts.

### DETAILED DESCRIPTION

Hereinafter, example embodiments of the present inventive concepts will be described with reference to the accompanying drawings, wherein like reference numerals refer to like elements throughout. In this regard, the present embodiments may have different forms and should not be construed as being limited to the descriptions set forth herein. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Additionally, when the terms “about”, “similar”, and/or “substantially” are used in this specification in connection with a numerical value and/or geometric terms, it is intended that the associated numerical value includes a manufacturing tolerance (e.g., ±10%) around the stated numerical value. Further, regardless of whether numerical values are modified as “about”, “similar”, and/or “substantially” it will be understood that these values should be construed as including a manufacturing or operational tolerance (e.g., ±10%) around the stated numerical values.

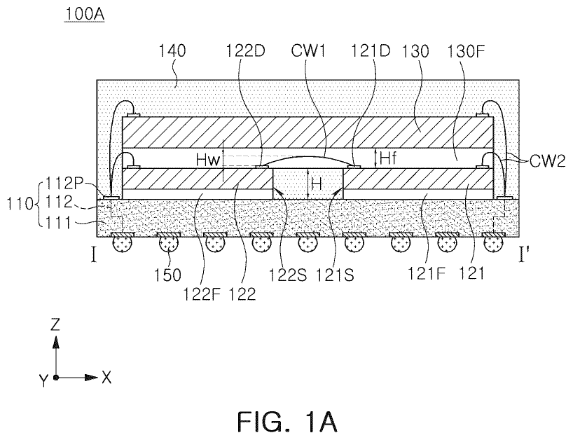

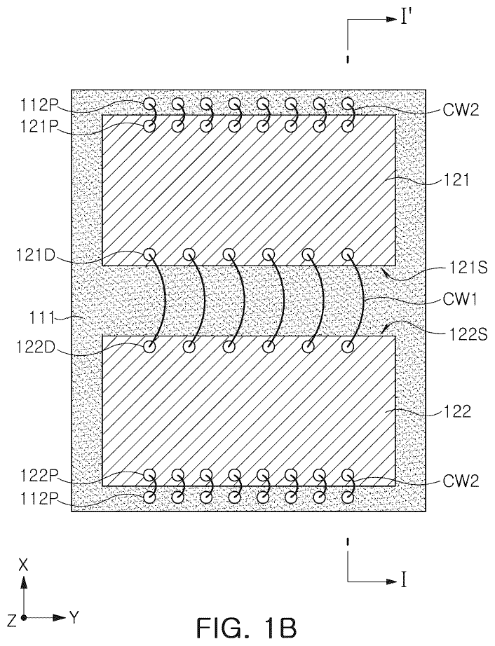

FIG. 1A is a cross-sectional view illustrating a semiconductor package 100A according to at least one example embodiment of the present inventive concepts, and FIG. 1B is a plan view illustrating some components of the semiconductor package 100A according to at least one example embodiment of the present inventive concepts. FIG. 1B illustrates the relationship between first and second lower semiconductor chips 121 and 122 and a package substrate 110.

Referring to FIGS. 1A and 1B, the semiconductor package 100A of at least one example embodiment includes a package substrate 110, a plurality of lower semiconductor chips 121 and 122, first connection wires CW1, an adhesive layer 130F, an upper semiconductor chip 130, second connection wires CW2, and an encapsulant 140. In addition, the semiconductor package 100A may further include a plurality of connection bumps 150 disposed below the package substrate 110.

In at least one example embodiment, the package substrate 110 includes an insulating layer 111, an interconnection layer 112, and interconnection pads 112P. The package substrate 110 may further include a via structure electrically connecting the interconnection layers 112 located on different levels. The package substrate 110 may be a semiconductor package substrate including a printed circuit board (PCB), a ceramic substrate, a glass substrate, a tape interconnection substrate, and/or the like.

The insulating layer 111 may include an insulating resin. The insulating resin may include, for example a thermosetting resin (such as an epoxy resin), a thermoplastic resin (such as polyimide), a resin obtained by impregnating these resins with an inorganic filler and/or glass fiber (glass fiber, glass cloth, or glass fabric) (such as a prepreg, Ajinomoto build-up film (ABF), FR-4, and bismaleimide triazine (BT)) and/or the like. In at least one example embodiment, the insulating resin may include a photosensitive resin, such as photoimageable dielectric (PID) resin. For example, when the package substrate 110 is a PCB substrate, the insulating layer 111 may be a core insulating layer (e.g., prepreg) of a copper clad laminate. The insulating layer 111 may have a form in which a plurality of insulating layers are stacked in a vertical direction (a Z-axis direction), and the boundaries between first insulating layers on different levels are not apparent depending on a process.

In at least one example embodiment, the interconnection layer 112 is disposed within the insulating layer 111 and may form an electrical path within the package substrate 110. The interconnection layer 112 may include a conductive material, such as at least one metal selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals thereof. The interconnection layer 112 may be provided with fewer or more layers than shown in the drawing (e.g., one layer or three or more layers).

In at least one example embodiment, the plurality of interconnection pads 112P are disposed on the insulating layer 111 around the plurality of lower semiconductor chips 121 and 122 and may be electrically connected to the plurality of lower semiconductor chips 121 and 122. In the drawing, a plurality of second connection wires CW2 are shown as being connected to one interconnection pad 112P, but the embodiments are not limited thereto, and the plurality of second connection wires CW2 may be connected through a separate interconnection pad 112P when the types of semiconductor chips to which the second connection wires CW2 are electrically connected are different.

In at least one example embodiment, the plurality of lower semiconductor chips 121 and 122 include a first lower semiconductor chip 121 and a second lower semiconductor chip disposed on the package substrate 110 and spaced apart from each other in a first direction (e.g., the X-axis direction). Each of the first and second lower semiconductor chips 121 and 122 may be attached to the insulating layer 111 of the package substrate 110 by adhesive members 121F and 122F (e.g., die-attach film (DAF)) and may be electrically connected to the interconnection layer 112 of the package substrate 110 by the second connection wires CW2.

In at least one example embodiment, a distance H from the top of the package substrate 110 to the top of the first lower semiconductor chip 121 may be equal to a distance from the top of the package substrate 110 to the top of the second lower semiconductor chip 122. A lower surface of the adhesive layer 130F may be in contact with an upper surface of the first lower semiconductor chip 121 and an upper surface of the second lower semiconductor chip 122 and may be parallel (coplanar and/or substantially coplanar) to an upper surface of the package substrate 110.

The first lower semiconductor chip 121 and the second lower semiconductor chip 122 may have, respectively, a first side 121S of the first lower semiconductor chip 121 and a second side 122S of the second lower semiconductor chip 122 facing each other, respectively. The first lower semiconductor chip 121 may include first dummy pads 121D disposed to be adjacent to the first side 121S, and the second lower semiconductor chip 122 may include second dummy pads 122D disposed to be adjacent to the second side 122S. In at least one example embodiment, the first dummy pads 121D and the second dummy pads 122D are disposed on the first lower semiconductor chip 121 and the second lower semiconductor chip 122, respectively, and may be located on the same level.

The first and second lower semiconductor chips 121 and 122 may include, for example, at least one of a logic chip (such as a central processor (CPU), a graphics processor (GPU), a field programmable gate array (FPGA), a digital signal processor, an encryption processor, a microprocessor, a microcontroller, an analog-to-digital converter (ADC), an application-specific IC (ASIC), and/or the like); and/or a memory chip (such as volatile memory (e.g., DRAM), non-volatile memory (e.g., ROM), flash memory, and/or the like). In at least one example embodiment, both the first and second lower semiconductor chips 121 and 122 are DRAM chips and may correspond to the same type of chips, but the examples are not limited thereto.

The first connection wires CW1 may extend from the first side 121S of the first lower semiconductor chip 121 to the second side 122S of the second lower semiconductor chip 122. The first connection wires CW1 may be arranged to connect the respective first dummy pads 121D and second dummy pads 122D. At least some of the first connection wires CW1 may be arranged in the first direction (the X-axis direction) to cross a region between the first side 121S and the second side 122S. The first connection wires CW1 may be arranged to pass through a space in which the first lower semiconductor chip 121 and the second lower semiconductor chip 122 are spaced apart from each other and may overlap the space in the vertical direction (the Z-axis direction). The plurality of first connection wires CW1 may be arranged to be spaced apart from each other in a second direction (a Y-axis direction) intersecting the first direction (the X-axis direction).

The adhesive layer 130F may be disposed on the first and second lower semiconductor chips 121 and 122. At least a portion of the adhesive layer 130F may overlap the first and second lower semiconductor chips 121 and 122 in the vertical direction (the Z-axis direction), and depending on at least one example embodiment, the adhesive layer 130F may be disposed to cover the entire upper surfaces of the first and second lower semiconductor chips 121 and 122, but is not limited thereto. The adhesive layer 130F may have a structure in which the first connection wires CW1 are embedded therein. The adhesive layer 130F may be, for example, a film layer formed of DAF and/or may have a film over wire (FOW) structure in which a wire is embedded therein. A vertical height Hf of the adhesive layer 130F may be greater than a height Hw from the lowermost end to the uppermost end of the first connection wires CW1. The adhesive layer 130F may surround the first connection wires CW1.

The upper semiconductor chip 130 may be disposed on the adhesive layer 130F. The upper semiconductor chip 130 may be the same size as that of the adhesive layer 130F on an X-Y plane. The upper semiconductor chip 130 may have characteristics the same as (and/or similar to) those of the lower semiconductor chips 121 and 122, and therefore the description of the upper semiconductor chip 130 may be the same as (and/or similar to) the description of the lower semiconductor chips 121 and 122 described above.

In at least one comparative example, the upper semiconductor chip 130 may sag down in the space in which the lower semiconductor chips 121 and 122 are spaced apart from each other. However, in the present inventive concepts, since the connection wires CW1 are embedded in the first connection wires CW1 in the adhesive layer 130F below the upper semiconductor chip 130, the upper semiconductor chip 130 may be prevented from being deformed in the vertical direction (the Z-axis direction). For example, the first connection wires CW1, traversing the space in which the lower semiconductor chips 121 and 122 are spaced apart from each other, may reinforce and/or supplement the rigidity of the adhesive layer 130F supporting the upper semiconductor chip 130 disposed thereon, and furthermore, improve the reliability of the entire package.

The second connection wires CW2 may electrically connect the lower semiconductor chips 121 and 122 and the upper semiconductor chip 130 to the interconnection layer 112 of the package substrate 110. The second connection wires CW2 may electrically connect at least one of the mounting pads 121P, 122P, and 130P respectively disposed on the lower semiconductor chips 121 and 122 and the upper semiconductor chip 130 and at least one of the interconnection pads 112P disposed on the insulating layer 111 of the package substrate 110. Among the second connection wires CW2, at least some of the second connection wires CW2 connected to the lower semiconductor chips 121 and 122 may be embedded in the adhesive layer 130F, and the second connection wires CW2 connected to the upper semiconductor chip 130, among the second connection wires CW2, may be embedded in the encapsulant 140.

The encapsulant 140 may be disposed on the package substrate 110 and may fill a space between the lower semiconductor chips 121 and 122. The encapsulant 140 may seal at least a portion of each of the plurality of lower semiconductor chips 121 and 122 and the upper semiconductor chip 130, on the package substrate 110. The encapsulant 140 may include an insulating material, for example, a thermosetting resin, such as an epoxy resin, a thermoplastic resin, such as polyimide, or a prepreg including an inorganic filler or/and glass fiber, ABF, FR-4, BT, epoxy molding compound (EMC), etc. For example, the encapsulant 140 may include the EMC.

In at least one example embodiment, the plurality of connection bumps 150 may have a shape of a land, ball, or a pin. In at least one example embodiment, the plurality of connection bumps 150 may include, for example, tin (Sn) or an alloy including tin (Sn) (e.g., Sn-Ag-Cu). The plurality of connection bumps 150 may be electrically connected to the interconnection layer 112 of the package substrate 110 and may be electrically connected to external devices, such as a module substrate and a system board.

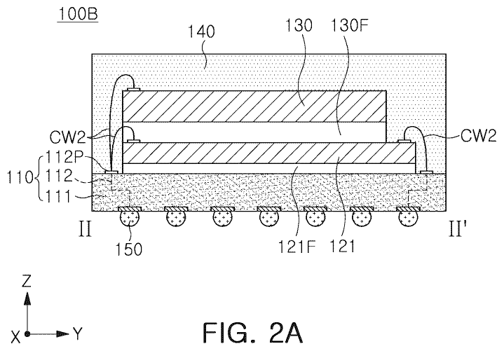

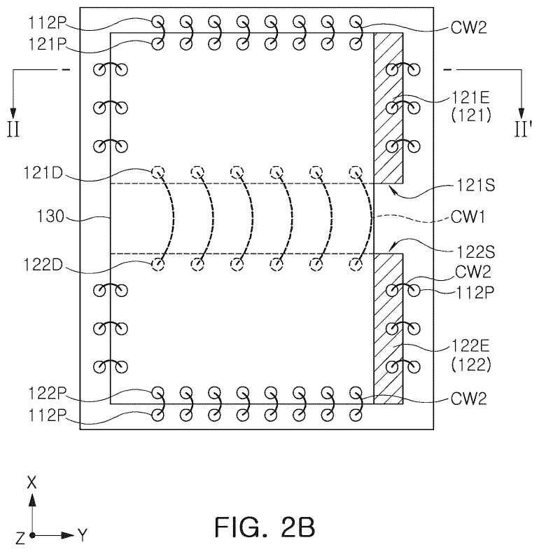

FIG. 2A is a cross-sectional view illustrating a semiconductor package according to at least one example embodiment of the present inventive concepts, and FIG. 2B is a top view illustrating the semiconductor package according to at least one example embodiment of the present inventive concepts.

Referring to FIGS. 2A and 2B, a semiconductor package 100B of at least one example embodiment may have characteristics that are the same as (and/or similar to) those described above with reference to FIGS. 1A and 1B, except that at least one of the two adjacent lower semiconductor chips 121 and 122 has exposed portions 121E and 122E extending to the outside of the adhesive layer 130F. At least some of the lower semiconductor chips 121 and 122 may include the exposed portions 121E and 122E not overlapping the upper semiconductor chip 130 and the adhesive layer 130F in the vertical direction (the Z-axis direction). The first connection wires CW1 connecting the first and second lower semiconductor chips 121 and 122 may be disposed in a region overlapping the upper semiconductor chip 130 in the vertical direction and may not be disposed in the exposed portions 121E and 122E. The second connection wires CW2 electrically connected to the package substrate 110 to the first exposed portion 121E of the first lower semiconductor chip 121 and the second exposed portion 122E of the second lower semiconductor chip 122 may be further arranged. The second connection wires CW2 disposed on the first exposed portion 121E and the second exposed portion 122E may be embedded in the encapsulant 140. By freely adjusting the region of the upper semiconductor chip 130 overlapping the lower semiconductor chips 121 and 122 in the vertical direction, the degree of freedom of the dolmen structure may increase, and by selectively disposing the first connection wires CW1 only in the region overlapping the upper semiconductor chip 130 in the vertical direction, the degree to which the upper semiconductor chip 130 is deformed may be minimized.

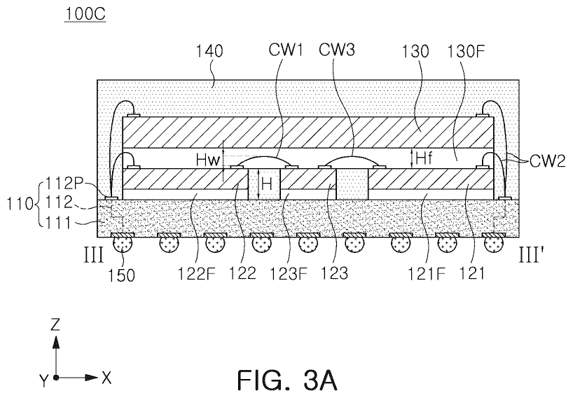

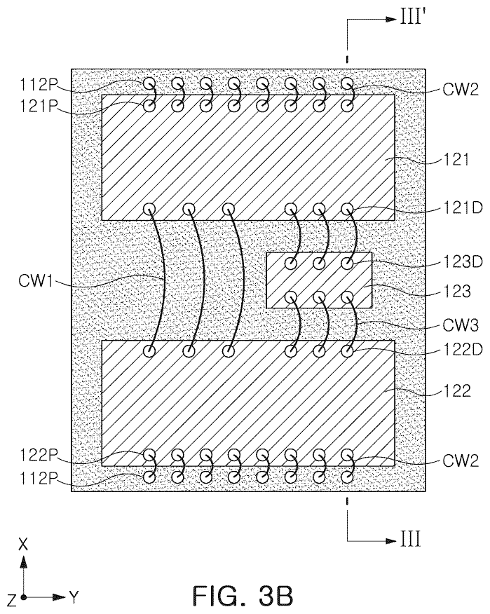

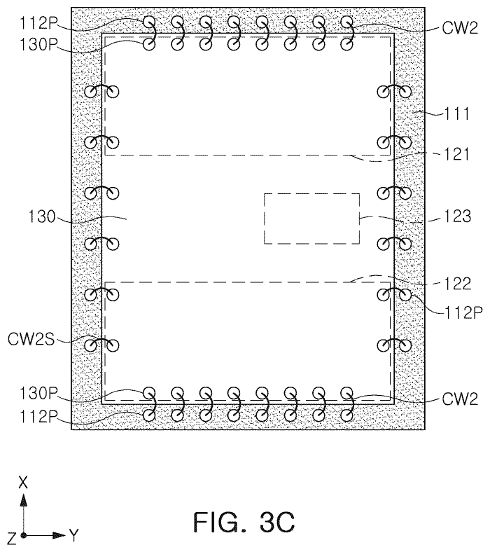

FIG. 3A is a cross-sectional view illustrating a semiconductor package 100C according to at least one example embodiment of the present inventive concepts, FIG. 3B is a plan view illustrating some components of the semiconductor package 100C according to at least one example embodiment of the present inventive concepts, and FIG. 3C is a top view illustrating the semiconductor package 100C according to at least one example embodiment of the present inventive concepts. FIG. 3B illustrates the relationship between the first and second lower semiconductor chips 121 and 122 and the package substrate 110.

Referring to FIGS. 3A to 3C, the semiconductor package 100C of at least one example embodiment may have characteristics that are the same as (and/or similar to) those described above with reference to FIGS. 1A to 2B, except that the semiconductor package 100C further includes a third lower semiconductor chip 123 disposed between the first and second lower semiconductor chips 121 and 122 and further includes third connection wires connecting at least one of the two lower semiconductor chips 121 and 122 to the third lower semiconductor chip 123. In at least one example embodiment, the first and second lower semiconductor chips 121 and 122 may be arranged to be spaced apart from each other in the first direction (the X-axis direction), and the third lower semiconductor chip 123 may be disposed between the first and second lower semiconductor chips 121 and 122. The third lower semiconductor chip 123 may include third dummy pads 123D at the top, and the third dummy pads 123D may be disposed to be spaced apart from each other in the first direction (the X-axis direction) and the second direction (the Y-axis direction) intersecting the first direction. At least one of the first dummy pads 121D of the first lower semiconductor chip 121 and at least one of the second dummy pads 122D of the second lower semiconductor chip 122 may be connected to respective third dummy pads 123D by the third connection wires CW3. The third connection wires CW3 may be arranged to be spaced apart from the first connection wires CW1 in the second direction (the Y-axis direction). In at least one example embodiment, when the first and second lower semiconductor chips 121 and 122 are memory chips, the third lower semiconductor chip 123 may include a memory controller and/or a frequency boosting interface (FBI) chip. The memory controller may determine a data processing order of the memory chip and may be configured to prevent (and/or mitigate) errors and defective sectors, and the FBI chip may increase an input/output (I/O) speed.

In at least one example embodiment, the third lower semiconductor chip 123 may be disposed to be adjacent to one side on the package substrate 110 in the second direction (the Y-axis direction). Referring to FIG. 3C, the second connection wires CW2 electrically connected to the upper semiconductor chip 130 may include second side connection wires CW2S disposed on the side opposite to the side adjacent to the third lower semiconductor chip 123. As the second side connection wires CW2S are connected from the top of the upper semiconductor chip 130 to the upper surface of the package substrate 110, a load may be applied to the longer side of the upper semiconductor chip 130. By disposing the first connection wires CW1 in the region adjacent to the upper side of the upper semiconductor chip 130, the adhesive layer 130F may withstand the load and bending of the upper semiconductor chip 130 may be minimized.

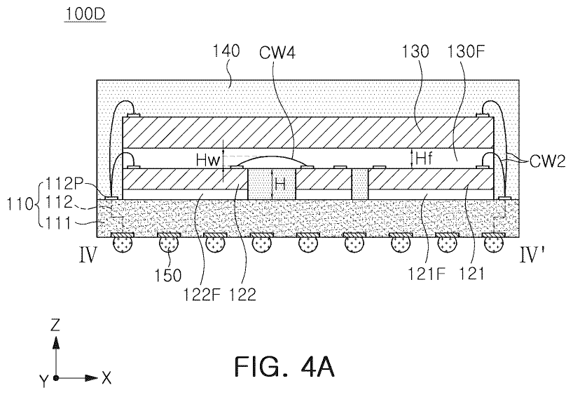

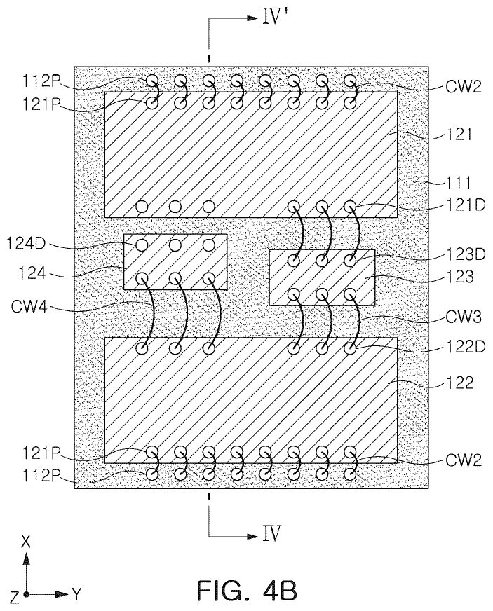

FIG. 4A is a cross-sectional view illustrating a semiconductor package according to at least one example embodiment of the present inventive concepts, and FIG. 4B is a plan view illustrating some components of the semiconductor package according to at least one example embodiment of the present inventive concepts. FIG. 4B illustrates the relationship between the first and second lower semiconductor chips 121 and 122 and the package substrate 110.

Referring to FIGS. 4A to 4B, a semiconductor package 100D of at least one example embodiment may have characteristics the same as or similar to those described above with reference to FIGS. 1A to 3C, except that a support member 124 disposed to be adjacent to a first side 121S of the first lower semiconductor chip 121 is further provided between the first and second lower semiconductor chips 121 and 122 and fourth connection wires CW4 connecting the second lower semiconductor chip 122 to the support member 124 is further provided. The support member 124 may have the same (and/or substantially the same) height as those of the first to third lower semiconductor chips 121, 122, and 123 to support the upper semiconductor chip 130. The support member 124 may include fourth dummy pads 124D at the top. The support member 124 may be disposed to be adjacent to at least one of the first lower semiconductor chip 121 and the second lower semiconductor chip 122. In at least one example embodiment, the support member 124 may be disposed to be adjacent to the first side 121S of the first lower semiconductor chip 121, and the fourth connection wires CW4 may connect the respective fourth dummy pads 124D and the second dummy pads 122D. In at least one example embodiment, the support member 124 may be a dummy semiconductor chip including a semiconductor material. In at least one example embodiment, the shape and material of the support member 124 may have various shapes and materials selected based on the relationship with surrounding elements (e.g., thermal expansion coefficient, elastic coefficient, etc.).

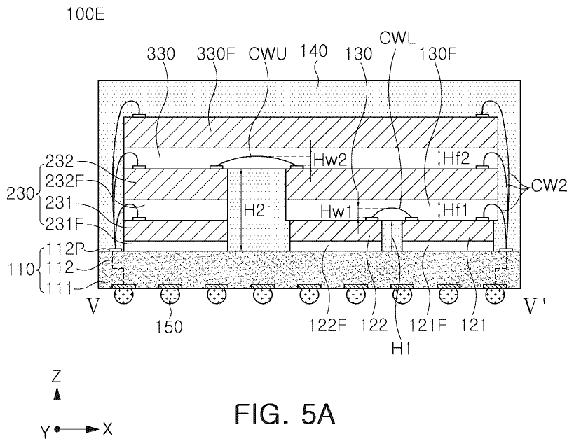

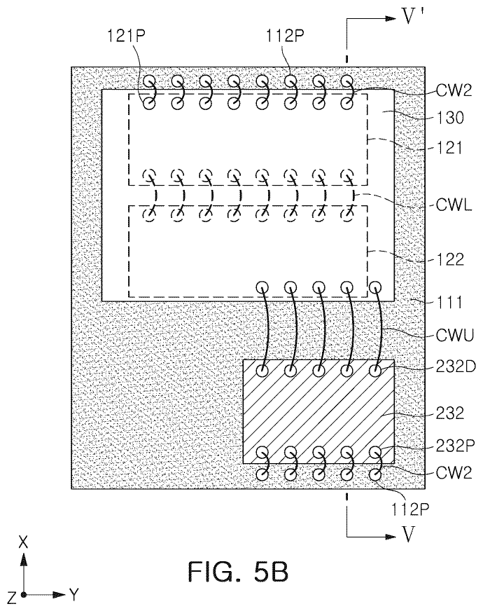

FIG. 5A is a cross-sectional view illustrating a semiconductor package according to at least one example embodiment of the present inventive concepts, and FIG. 5B is a top view illustrating some components of the semiconductor package according to at least one example embodiment of the present inventive concepts. FIG. 5B illustrates the relationship between the first chip structure, the second chip structure 230, and the package substrate 110.

Referring to FIGS. 5A to 5B, a semiconductor package 100E of at least one example embodiment may have characteristics the same as (and/or similar to) those described above with reference to FIGS. 1A to 4B, except that a first chip structure including lower connection wires CWL connected to a second chip structure 230 by upper connection wires CWU. The first chip structure may include lower connection wires CWL connecting the plurality of lower semiconductor chips 121 and 122 spaced apart from each other, a lower adhesive layer 130F covering the lower connection wires CWL, and an upper semiconductor chip 130 disposed on the lower adhesive layer 130F. A height of the lower adhesive layer 130F may be greater than a height Hw1 from the lowermost end to the uppermost end of each of the lower connection wires CWL. The second chip structure 230 may be spaced apart from the first chip structure in the first direction (the X-axis direction) and may include a plurality of chips 231 and 232 stacked in the vertical direction (the Z-axis direction), but is not limited thereto. A height of the plurality of chips 231 and 232 and the adhesive members 231F and 232F connecting the plurality of chips 231 and 232 may be equal to respective components of the first chip structure located on the same level. The upper connection wires CWU may connect the first chip structure to the second chip structure 230, and the upper adhesive layer 330F may cover the upper connection wires CWU. Since the upper connection wires CWU and the upper adhesive layer 330F have characteristics the same as (and/or similar to) those of the lower connection wires CWL and the lower adhesive layer 130F, the description of the upper connection wires CWU and the upper adhesive layer 330F may be redisposed with the description of the lower connection wires CWL and the lower adhesive layer 130F. A height Hf2 of the upper adhesive layer 330F may be equal to a height Hf1 of the lower adhesive layer 130F, but is not limited thereto. The plurality of lower semiconductor chips 121 and 122 may have the same height H1, and the first chip structure may have the same height H2 as that of the second chip structure 230.

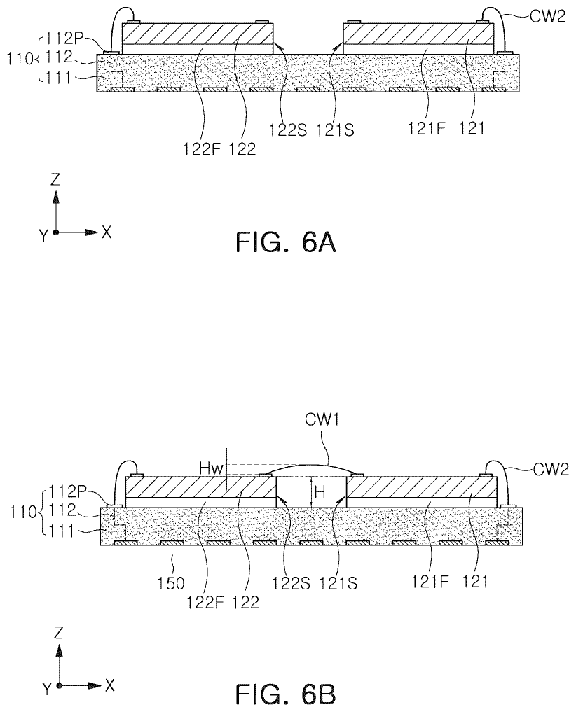

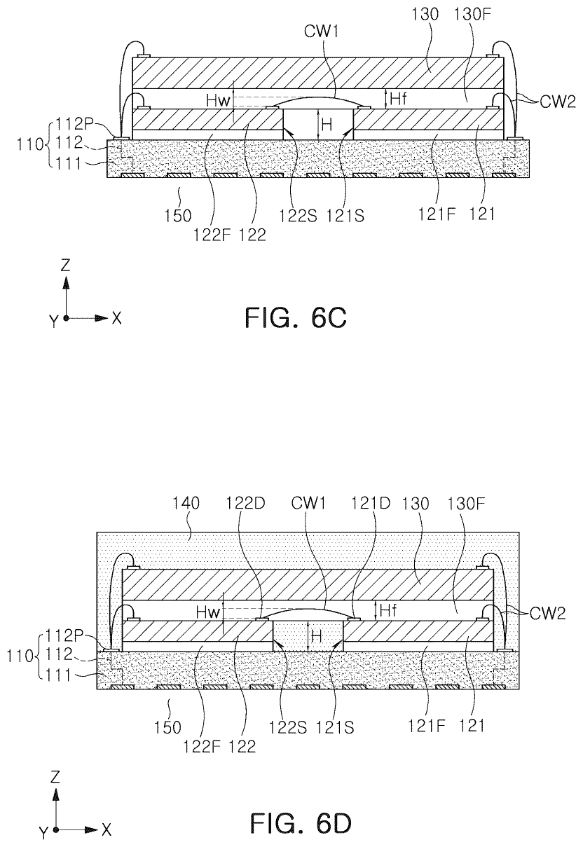

FIGS. 6A to 6D are cross-sectional views illustrating a main process of a method of manufacturing a semiconductor package according to at least one example embodiment of the present inventive concepts.

Referring to FIG. 6A, a plurality of lower semiconductor chips 121 and 122 may be disposed on the package substrate 110. The package substrate 110 may include an insulating layer 111 and an interconnection layer 112 disposed within the insulating layer 111. Interconnection pads 112P electrically connected to the interconnection layer 112 may be disposed on the upper surface of the package substrate 110. The first and second lower semiconductor chips 121 and 122 may be attached to the package substrate 110 through adhesive members 121F and 122F, respectively. The first side 121S of the first lower semiconductor chip 121 and the second side 122S of the second lower semiconductor chip 122 may be arranged to face each other. The first and second lower semiconductor chips 121 and 122 may be electrically connected to the interconnection layer 112 of the package substrate 110 through the interconnection pads 112P and the second connection wires CW2.

Referring to FIG. 6B, the first connection wires CW1 may connect the first and second lower semiconductor chips 121 and 122. The first dummy pads 121D may be disposed to be adjacent to the first side 121S of the first lower semiconductor chip 121, and the second dummy pads 122D may be disposed to be adjacent to the second side 122S of the second lower semiconductor chip 122. The first connection wires CW1 may connect the first dummy pads 121D and the second dummy pads 122D. The first connection wires CW1 may extend in the first direction (the X-axis direction) and may be arranged across a space in which the first and second lower semiconductor chips 121 and 122 are spaced apart from each other.

Referring to FIG. 6C, the adhesive layer 130F and the upper semiconductor chip 130 may be disposed on the first lower semiconductor chip 121, the second lower semiconductor chip 122, and the first connection wires CW1. The adhesive layer 130F may be an insulating material layer and may be a layer, such as a DAF. The adhesive layer 130F may be disposed on the first connection wires CW1 to surround the first connection wires CW1. The height Hf of the adhesive layer 130F may be greater than the height Hw from the lowermost end to the uppermost end of the first connection wires CW1. The first connection wires CW1 may not be exposed from the adhesive layer 130F, but may have a structure entirely impregnated in the adhesive layer 130F. At least some of the second connection wires CW2 may have a portion embedded in the adhesive layer 130F. The upper semiconductor chip 130 may be electrically connected to the package substrate 110 through second connection wires CW2.

Referring to FIG. 6D, the encapsulant 140 may be formed on the package substrate 110. The encapsulant 140 may cover at least a portion of the lower semiconductor chips 121 and 122 and the upper semiconductor chip 130. The encapsulant 140 may cover at least a portion of the second connection wires CW2. At least some of the second connection wires CW2 may have both a portion embedded in the adhesive layer 130F and a portion embedded in the encapsulant 140. The encapsulant 140 may fill a space in which the first and second lower semiconductor chips 121 and 122 are spaced apart from each other. Depending on at least one example embodiment, the encapsulant 140 may fill the space between the third lower semiconductor chip 123 (see FIG. 3A) and the support member 124 (see FIG. 4A).

Referring to FIGS. 1A and 1B, a plurality of connection bumps 150 may be formed below the package substrate 110. The connection bumps 150 may be electrically connected to the interconnection layer 112.

According to embodiments of the present inventive concepts, the semiconductor package having improved reliability may be provided by forming the bonding wire between the lower semiconductor chips supporting the upper semiconductor chip.

While example embodiments have been shown and described above, it will be apparent to those skilled in the art that modifications and variations could be made without departing from the scope of the present inventive concepts as defined by the appended claims.

What is claimed is:

1. A semiconductor package comprising:
a package substrate including an insulating layer, an interconnection layer in the insulating layer, and interconnection pads on the insulating layer and electrically connected to the interconnection layer;
first and second lower semiconductor chips over the package substrate, the first and second lower semiconductor chips spaced apart from each other in a first direction;
first connection wires extending from a first side of the first lower semiconductor chip towards a second side of the second lower semiconductor chip, the first connection wires spaced apart from each other in a second direction, the second direction intersecting the first direction;
an adhesive layer over the first and second lower semiconductor chips, the adhesive layer covering at least a portion of each of the first connection wires;
an upper semiconductor chip over the adhesive layer;
second connection wires electrically connecting the first and second lower semiconductor chips and the upper semiconductor chip to the interconnection layer of the package substrate; and
an encapsulant on the package substrate, the encapsulant filling a space between the first and second lower semiconductor chips.

2. The semiconductor package of claim 1, wherein
the first lower semiconductor chip further includes first dummy pads adjacent to the first side,
the second lower semiconductor chip further includes second dummy pads adjacent to the second side, and
each of the first connection wires connects a first dummy pad, of the first dummy pads, to a corresponding second dummy pad of the second dummy pads.

3. The semiconductor package of claim 2, wherein the first and second dummy pads are located at a same level.

4. The semiconductor package of claim 1, wherein an upper surface of the first and second lower semiconductor chips are located at a same level.

5. The semiconductor package of claim 1, further comprising:
a third lower semiconductor chip between the first and second lower semiconductor chips; and
third connection wires connecting at least one of the first and second lower semiconductor chips to the third lower semiconductor chip.

6. The semiconductor package of claim 5, wherein an upper surface of the third lower semiconductor chip is located at a same level as upper surfaces of the first and second lower semiconductor chips.

7. The semiconductor package of claim 5, wherein the first connection wires and the third connection wires are spaced apart from each other in the second direction.

8. The semiconductor package of claim 1, further comprising:
a support member between the first and second lower semiconductor chips, the support member nearer to the first side of the first lower semiconductor chip than to the second side of the second lower semiconductor chip; and
fourth connection wires connecting the second lower semiconductor chip to the support member.

9. The semiconductor package of claim 1, further comprising:
adhesive members attaching the first and second lower semiconductor chips to the package substrate,
wherein a height of the adhesive layer is greater than heights of the adhesive members.

10. The semiconductor package of claim 1, wherein at least a portion of each of the first connection wires crosses a region between the first side and the second side when viewed in cross section.

11. The semiconductor package of claim 1, wherein a height of the adhesive layer is greater than a height from a lowermost point to an uppermost point of each of the first connection wires.

12. The semiconductor package of claim 1, wherein the first and second lower semiconductor chips are a same type of chip.

13. A semiconductor package comprising:
a package substrate;
a plurality of lower semiconductor chips spaced apart from each other on the package substrate;
first connection wires overlapping a space between two adjacent lower semiconductor chips, among the plurality of lower semiconductor chips, in a vertical direction, the first connection wires connecting the two adjacent lower semiconductor chips;
second connection wires electrically connecting at least one of the plurality of lower semiconductor chips to the package substrate;
an adhesive layer over the plurality of lower semiconductor chips, the adhesion layer covering at least a portion of each of the first connection wires;
an upper semiconductor chip on the adhesive layer; and
an encapsulant covering at least a portion of each of the upper semiconductor chip and the plurality of lower semiconductor chips.

14. The semiconductor package of claim 13, wherein
at least one of the two adjacent lower semiconductor chips includes an exposed portion extending outside of the adhesive layer, and
the first connection wires are not on the exposed portion.

15. The semiconductor package of claim 14, wherein
at least one of the second connection wires extend from the exposed portion to the package substrate, and
each of the at least one of the second connection wires is entirely embedded in the encapsulant.

16. The semiconductor package of claim 13, wherein at least one of the second connection wires has a portion embedded in the adhesive layer and a portion matched to the encapsulant.

17. A semiconductor package comprising:
a package substrate;
a first chip structure including
a plurality of lower semiconductor chips on the package substrate and spaced apart from each other,
lower connection wires connecting the plurality of lower semiconductor chips,
a lower adhesive layer on the plurality of lower semiconductor chips and covering the lower connection wires, and
an upper semiconductor chip on the lower adhesive layer;
a second chip structure spaced apart from the first chip structure;
upper connection wires connecting the first and second chip structures to each other;
an upper adhesive layer on each of the first and second chip structures and covering the upper connection wires; and
an uppermost semiconductor chip on the upper adhesive layer

18. The semiconductor package of claim 17, wherein the second chip structure includes a plurality of semiconductor chips stacked in a vertical direction.

19. The semiconductor package of claim 17, wherein upper surfaces of the first and second chip structures are located on a same level.

20. The semiconductor package of claim 17, wherein the upper connection wires are located at a higher level than the lower connection wires.
